(19) United States
(12) Patent Application Publication
(10) Pub. No.: US 2019/0291214 A1
(43) Pub. Date: Sep. 26, 2019

(54) LASER POLISHING CERAMIC SURFACES OF PROCESSING COMPONENTS TO BE USED IN THE MANUFACTURING OF SEMICONDUCTOR DEVICES

(71) Applicant: Applied Materials, Inc., Santa Clara, CA (US)

(72) Inventors: Gang Grant PENG, Fremont, CA (US); David W. GROECHEL, Los Altos Hills, CA (US); Tuochuan HUANG, Saratoga, CA (US)

(21) Appl. No.: 16/359,643

(22) Filed: Mar. 20, 2019

Related U.S. Application Data
(60) Provisional application No. 62/646,571, filed on Mar. 22, 2018.

(51) Int. Cl. B23K 26/352; B23K 26/0622; H01J 37/32

(52) U.S. Cl. CPC B23K 26/3576; H01J 37/32495; B23K 26/0622

(57) ABSTRACT

Embodiments of the present disclosure provide methods of laser assisted modification, i.e., laser polishing, of ceramic substrates, or ceramic coated substrates, to desirably reduce the surface roughness and porosity thereof. In one embodiment, a method of laser polishing a workpiece surface includes scanning at least a portion of the workpiece surface with a pulsed laser beam. The laser beam has a pulse frequency of about 50 kHz or more and a spot size of about 10 mm² or less and the workpiece surface comprises a ceramic material.

### CROSS-REFERENCE TO RELATED APPLICATIONS

This application claims priority to U.S. Provisional Application Ser. No. 62/646,571 filed on Mar. 22, 2018, which is herein incorporated by reference in its entirety.

### BACKGROUND

### Field

Embodiments of the present disclosure generally relate to semiconductor device manufacturing. In particular, embodiments herein relate to laser polishing surfaces of components used with or in a plasma processing chamber.

### Description of the Related Art

Often, semiconductor device manifesting equipment, such as plasma assisted processing chambers and processing components related thereto, are formed of a ceramic material or a substrate having a protective ceramic material coating deposited thereon. The ceramic materials provide desired resistance to chemical corrosion or plasma based erosion which would otherwise shorten the useful lifetime of the processing component.

Unfortunately, as-deposited ceramic coatings often have a greater than desired surface roughness and porosity than that of the underlying component material on which they have been deposited. A protective ceramic coating having undesirably high surface roughness and porosity is susceptible to cracking and flaking, and thus generating particles in a processing chamber in which it is sued which particles can ultimately transfer to a device side surface of a substrate disposed therein. Particle contamination of a substrate during the manufacturing of devices thereon will often render a device inoperable resulting in suppressed device yield from a contaminated substrate.

Accordingly, there is a need in the art for improved surface finishing methods of ceramic processing components and ceramic coated surfaces of processing components.

### SUMMARY

Embodiments of the present disclosure provide methods of laser assisted modification, i.e., laser polishing, of ceramic substrates, or ceramic coated substrates, to desirably reduce the surface roughness and porosity thereof.

In one embodiment, a method of laser polishing a workpiece surface includes scanning at least a portion of the workpiece surface with a pulsed laser beam. The laser beam has a pulse frequency of about 50 kHz or more and a spot size of about 10 mm² or less and the workpiece surface comprises a ceramic material.

In one embodiment, a method of laser polishing a workpiece surface includes scanning at least a portion of the workpiece surface with a pulsed laser beam having a pulse frequency of about 50 kHz or more and a spot size of about 10 mm or less. Here, the workpiece surface comprises a ceramic material and the workpiece is a processing component for use with a plasma processing chamber, comprising one of a gas injector, a showerhead, a substrate support, a support shaft, a door, a liner, a shield, or a robot end effector.

In one embodiment, a method of laser polishing a workpiece surface includes scanning at least a portion of the workpiece surface with a pulsed laser beam having a pulse frequency of about 50 kHz or more and a spot size of about 10 mm² or less. Here, the workpiece surface comprises quartz or a nitride, fluoride, oxide, oxynitride, or an oxyfluoride of aluminum, titanium, tantalum, or yttrium and the workpiece is a processing component for use with a plasma processing chamber, the workpiece comprising one of a gas injector, a showerhead, a substrate support, a support shaft, a door, a liner, a shield, or a robot end effector.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a cross-sectional schematic view of a processing chamber having one or more processing components which have been polished using the laser assisted surface modification (laser polishing) methods described herein, according to one embodiment.

FIG. 2A is a schematic isometric view of a substrate support having one or more surfaces polished using the laser polishing methods described herein, according to one embodiment.

FIG. 2B is a close up isometric sectional view of a portion of the substrate support shown in FIG. 2A.

FIG. 3 is a schematic representation of a laser polishing system which may be used to practice the methods set forth herein, according to one embodiment.

FIG. 4 sets forth a method of laser polishing a workpiece surface using the laser polishing system described in FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

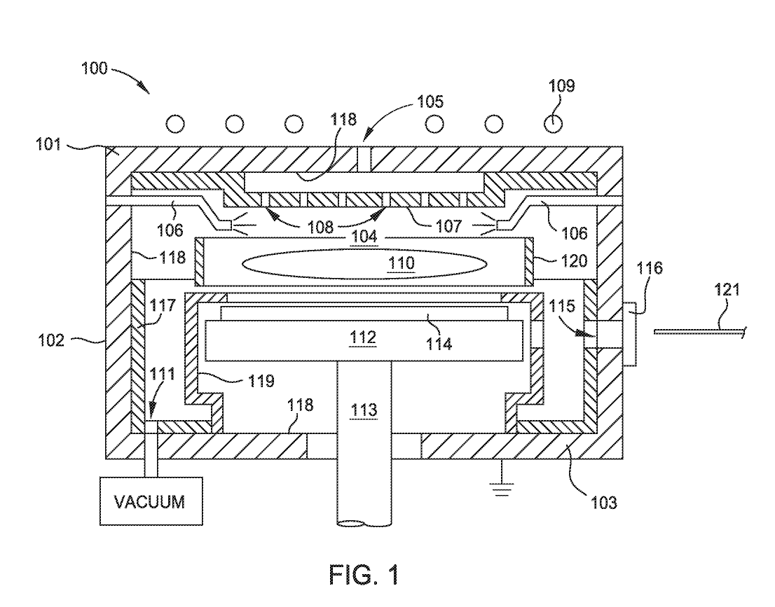

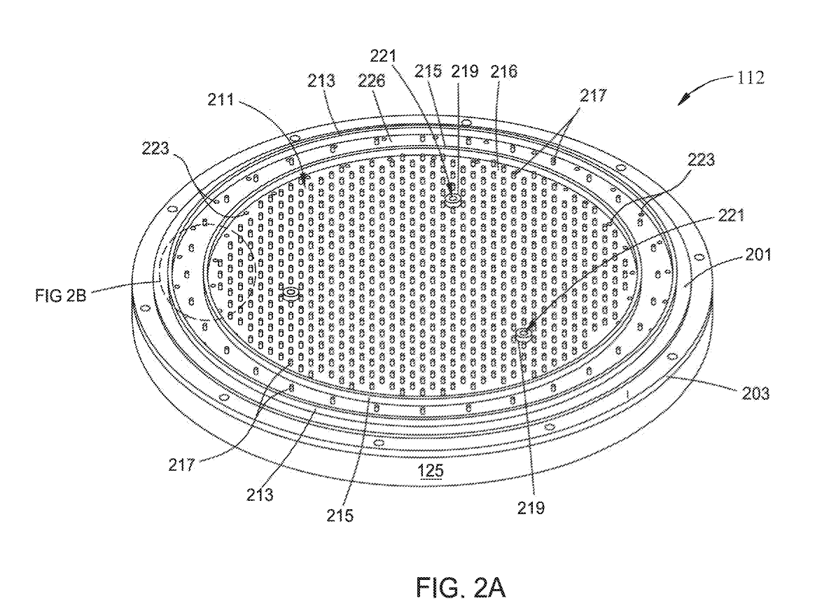

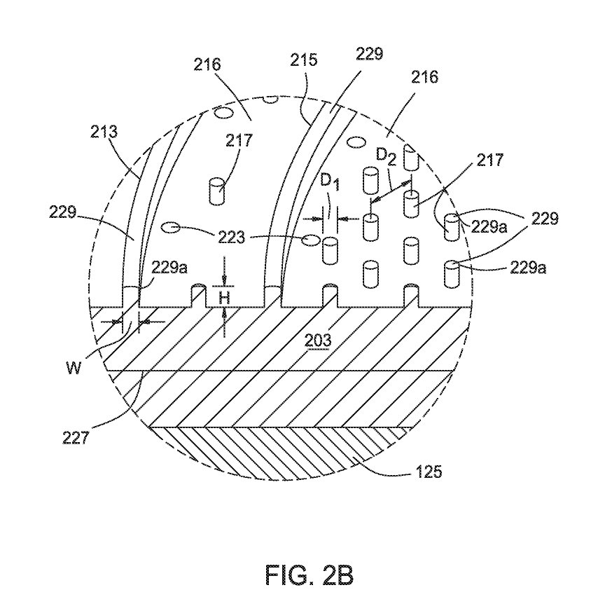

Embodiments of the present disclosure provide methods of laser assisted modification, i.e., laser polishing, of ceramic substrates, or ceramic coated substrates, to desirably reduce the surface roughness and porosity thereof. The laser polishing methods described herein beneficially allow precision sub-millimeter scale polishing control on the surface area(s) to be polished and thus provide desirably high resolution between surface regions where material polishing is desired and adjacently disposed surface regions, or opening formed therein, where material polishing is not desired. In some embodiments, the methods described herein are used to polish ceramic processing chamber components, or ceramic coated surfaces of processing chamber components, which may be used in the field of electronic device manufacturing, e.g., semiconductor device manufacturing. Examples of processing chamber components which may benefit for the laser polishing methods described herein are shown and described in FIGS. 1 and 2A-2B. Beneficially, the laser polishing methods provided herein, unlike mechanical polishing, do not require substantial material removal from the surface to be polished. Thus, the methods provided herein enable the surface modification of both recessed surfaces and elevated features of a patterned surface without risking undesirably planarization of elevated features therefrom, such as the patterned surface of the substrate support further described in FIGS. 2A and 2B.

FIG. 1 is a cross-sectional schematic view of a processing chamber 100 having one or more processing components which have been polished using the laser assisted surface modification (laser polishing) methods described herein, according to one embodiment The processing chamber 100 shown in FIG. 1 is a plasma assisted etch chamber. However, it is contemplated that the laser polishing methods described herein may be used to polish processing components used in any plasma assisted processing chamber or on any other ceramic surface where high resolution polishing is desired.

The processing chamber 100 features a chamber body which includes a chamber lid 101, one or more sidewalls 102, and a chamber base 103. Here, the processing chamber further includes a substrate support 112 and a showerhead 107 which, with the one or more sidewalls 102, collectively define a processing volume 104. Typically, processing gases are delivered to the processing volume 104 though an inlet 105 disposed through the chamber lid 101, through one or more gas injectors 106 disposed through the one or more sidewalls 102, or both. The showerhead 107, having a plurality of holes 108 disposed therethrough, is used to uniformly distribute processing gases into the processing volume 104. Typically, the diameter of the holes 108 is about 5 mm or less, such as about 3 mm or less, for example about 1 mm less. In some embodiments, individual ones of the holes 108 are spaced apart so that the width of material disposed therebetween on the plasma facing surface of the showerhead is about 10 mm or less.

The processing chamber 100 features an inductively coupled plasma (ICP) generated by passing an A.C. frequency, such as an RF frequency, through one or more inductive coils 109 disposed proximate to the chamber lid 101 outside of the processing volume 104. The chamber lid 101 and the showerhead 107 are formed of dielectric material, such as quartz. The chamber lid 101 and the showerhead 107 form a dielectric window through which the electromagnetic energy generated by the inductive coils 109 is coupled to a plasma 110 formed of a gas within the processing volume 104. The electromagnetic field imposed on the gases in the processing volume 104 from the A.C. power on the coil is used to ignite and maintain the plasma 110 using an inert gas and in some cases the processing gases in a processing volume 104.

Here, the processing volume 104 is fluidly coupled to a vacuum source, such as to one or more dedicated vacuum pumps, through a vacuum outlet 111, which maintains the processing volume 104 at sub-atmospheric conditions and evacuates the processing gas and other gases therefrom. A substrate support 112, disposed in the processing volume 104, is disposed on a movable support shaft 113 sealingly extending through the chamber base 103, such as being surrounded by bellows (not shown) in the region below the chamber base 103. Typically, the substrate support 112 includes a chucking electrode (not shown) embedded in the dielectric material thereof which secures the substrate 114 to the substrate support 112 by providing a potential between the substrate 114 and the chucking electrode.

Often, the substrate support 112 is used to maintain the substrate 114 at a desired temperature or within a desired range of temperatures, by heat transfer between the dielectric material of the substrate support 112 and the substrate 114 disposed thereon. For example, in some embodiments, the substrate support 112 includes a heating element (not shown), embedded in the dielectric material thereof, that is used to heat the substrate support 112, and thus the substrate 114, to a desired temperature before processing and to maintain the substrate 114 at a desired temperature during processing. For other semiconductor manufacturing processes, it is desirable to cool the substrate 114 during the processing thereof and the substrate support 112 is thermally coupled to a cooling base (not shown), typically comprising one or more cooling channels having a cooling fluid flowing therethrough. In some cases, the substrate support 112 includes both heating elements and cooling channels, which facilitate fine control of the temperature of the substrate support 112.

Typically, a low pressure atmosphere in the processing volume 104 of a processing chamber will results in poor thermal conduction between the dielectric material of the substrate support 112 and the substrate 114, which reduces the substrate support's effectiveness in heating or cooling the substrate 114. Therefore, in some processes, a thermally conductive inert gas, typically helium, is introduced into a backside volume (not shown) disposed between the non-device side surface of the substrate 114 and the substrate support 112 to improve the heat transfer therebetween. The backside volume is defined by one or more recessed surfaces in a patterned surface of the substrate support 112, such as the patterned surface 201 described in FIGS. 2A-2B, and the substrate 114 disposed thereon. In some embodiments, at least portions of the patterned surface 201 of the substrate support 112 are laser polished using the methods described herein.

Here, the processing chamber 100 is configured to facilitate transferring of a substrate 114 to and from the substrate support 112 through an opening 115 in one of the one or more sidewalls 102, which is sealed with a door 116 or a valve during substrate processing. For example, in some embodiments, a plurality of lift pins (not shown) are movably disposed through corresponding lift pin openings 221 (shown in FIGS. 2A and 2B) formed through the substrate support 112 to facilitate transferring of the substrate 114 thereto and therefrom. When the plurality of lift pins are in a raised position, the substrate 114 is lifted from the substrate support 112 to enable access to the substrate 114 by a robot handler. When the plurality of lift pins are in a lowered position the upper surfaces thereof are flush with, or below, a surface of the substrate support 112 and the substrate rests thereon.

The processing chamber 100 here includes one or more removable liners 117 disposed on and radially inward from one or more interior surfaces 118 of the chamber body. The processing chamber 100 further includes one or more shields, such as the first shield 119 circumscribing the substrate support 112 and support shaft 113 and a second shield 120 disposed radially inward from the one or more sidewalls 102. Herein, the shields 119 and 120 are used confine the plasma 110 to a desired region in the processing volume 104, to define flow pathways for gases in the processing volume 104, to protect the chamber walls from the process gases and deposition products or etchants, or combinations thereof. In some embodiments, the substrate 114 is transferred into and out of the processing volume using a robot end effector, e.g., a robot vacuum wand 121.

In embodiments herein, the surfaces of one or more of the processing components described above are formed of a ceramic material, have a protective ceramic material coating disposed thereon, or both. Examples of suitable ceramics for use as a processing component or a protective coating for a processing component include silicon carbide (SiC), quartz, or fluorides, oxides, oxyfluorides, nitrides, and oxynitrides of Group III, Group IV, Lanthanide series elements, and combinations thereof. For example, in some embodiments, the surfaces of one or more of the processing components described above are formed of quartz, aluminum oxide (Al₂O₃), aluminum nitride (AlN), titanium oxide (TiO), titanium nitride (TiN), tantalum oxide (Ta₂O₅), tantalum nitride (TaN), yttrium oxide (Y₂O₃), yttrium fluoride (YF₃), yttrium oxyfluoride (YOF), or yttrium-stabilized zirconia.

Often the ceramic coatings are deposited onto at least a plasma facing surface of a processing component to protect the underlying component material from chemical corrosion and plasma based erosion. The ceramic coating is deposited using any suitable coating method, such as a thermal spraying method, e.g., plasma spraying, where the ceramic coating material is heated to a molten or a plasticized state and sprayed onto the surface the processing component. For example, in some embodiments, the processing component is a showerhead, such as the showerhead 107, formed of a quartz substrate and having an yttrium based ceramic coating deposited onto at least the plasma facing surface thereof. In other embodiments, the plasma facing surface of the showerhead 107 is formed of quartz and the laser polishing methods described herein are used to repair plasma induced erosion thereof, thus extending the useful lifetime of the showerhead 107.

In other embodiments, the showerhead is formed of an electrically conductive material, such as aluminum, and a capacitively coupled plasma (CCP) is maintained between the showerhead and the chamber wall or substrate support 112. In other embodiments, a microwave source is used to generate a plasma in the processing volume using an inert and in some cases the process gases. In some embodiments, a gas plasma is generated remotely from the processing volume 104 using a remote plasma source (not shown) before being delivered thereinto.

FIG. 2A is a schematic isometric view the substrate support 112 which features one or more ceramic surfaces polished using the laser polishing methods described herein. FIG. 2B is a close-up isometric sectional view of a portion of the substrate support 112 shown in FIG. 2A.

Here, the substrate support 112 features a patterned surface 201 having a plurality of elevated features extending from one or more recessed surfaces 216. The elevated features include a plurality of protrusions 217, one or more outer sealing bands, such as a second outer sealing band 215 and a first outer sealing band 213, and a plurality of inner sealing bands 219. The first outer sealing band 213 is concentrically disposed about the center of the patterned surface 201 and proximate to an outer circumference thereof and the second outer sealing band 215 is concentrically disposed about the center of the patterned surface 201 proximate to, and radially inward of, the first outer sealing band 213. Each of the inner sealing bands 219 are coaxially disposed about respective lift pin openings 221 formed through the substrate support 112. The elevated features and one or more recessed surfaces 216, and the non-device side surface of a substrate 114 (shown in FIG. 1) define the boundary surfaces of a backside volume when the substrate 114 is chucked to the substrate support 112.

As shown, the plurality of protrusions 217 are substantially cylindrically shaped and have a mean diameter D₁ of between about 500 μm and about 5 mm, a center to center (CTC) spacing D₂ of between about 5 mm and about 20 mm, and the height H of between about 3 μm and about 700 μm. In other embodiments, the plurality of protrusions 217 comprise any other suitable shape such as square or rectangular blocks, cones, wedges, pyramids, posts, cylindrical mounds, or other protrusions of varying sizes, or combinations thereof that extend beyond the recessed surface 216 to support the substrate 114 and are formed using any suitable method.

Here, the first outer and second outer sealing bands 213 and 215 have a substantially rectangular cross sectional profile, with a height H and a width between about 500 μm and about 5 mm. The plurality of inner sealing bands 219, one of each surrounding each lift pin opening, typically have a substantially rectangular shaped cross sectional profile, between an inner diameter and an outer diameter thereof with the height H and the width W. The plurality of protrusions 217, at least, hold the substrate 114 spaced from the recessed surface 216 when the substrate 114 is chucked to the substrate support 112, which allows a thermally conductive inert gas, herein helium, to flow from the gas inlet throughout the backside volume between the substrate 114 and the substrate support 112. The sealing bands 213, 215, and 219 prevent, or significantly curtail, gas from flowing from the backside volume into the processing volume 104 of the processing chamber 100 when the substrate 114 is chucked to the substrate support 112 (shown in FIG. 1).

In other embodiments, the plurality of protrusions 217 comprise any other suitable shape such as square or rectangular blocks, cones, wedges, pyramids, posts, cylindrical mounds, or other protrusions of varying sizes, or combinations thereof that extend beyond the recessed surface 216 to support the substrate 114 and are formed using any suitable method. In some embodiments, the contact area between the between the substrate contact surfaces 229 of the substrate support 112 and the non-device side surface of a substrate disposed thereon is less than about 30%, such as less than about 20%, such as less than about 15%, less than about 10%, less than about 5%, for example less than about 3%.

Typically, the patterned surface 201 of the substrate support 112 is formed using an additive manufacturing process, a subtractive manufacturing process, or a combination thereof. In a typical additive manufacturing process, the elevated features are deposited onto a pre-pattern surface of the substrate support 112 though a mask having corresponding openings there though. The pre-pattern surface which will form the recessed surfaces 216 of substrate support 112 is typically planarized or otherwise processed to a desired surface finish before deposition of the elevated features. However, the substrate contacting features of the elevated surfaces often have undesirably high surface roughness and are thus, in some embodiments, laser polished using the methods described herein.

In a typical subtractive manufacturing process, material from the to be formed recessed regions is removed, e.g., by bead blasting, from a pre-pattern surface of the substrate support though corresponding openings formed through a disposed thereon. Like the additive manufacturing process, the pre-pattern surface which will form the substrate contacting surfaces is typically planarized or otherwise processed to a desired surface finish before removal of material from the to be formed recessed regions. However, the surfaces 216 in the recessed regions often have undesirably high surface roughness and are thus, in some embodiments, laser polished using the methods described herein.

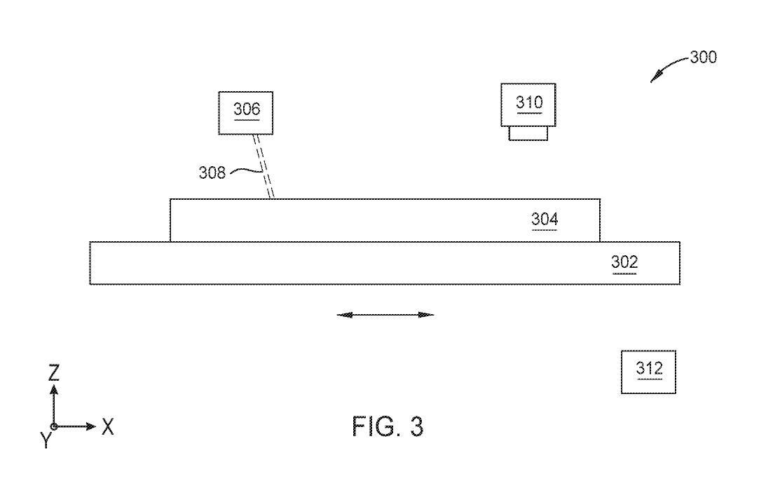

FIG. 3 is a schematic representation of a laser polishing system 300 which may be used to practice the methods set forth herein, according to one embodiment. The laser polishing system 300 features a translational stage 302, for supporting and positioning a workpiece 304 disposed thereon, and a scanning laser source 306. Here, the scanning laser source 306 is disposed above the stage 302 and faces there towards to direct a pulsed laser beam 308 onto a surface of the to be polished workpiece 304. In other embodiments, the laser source 306 is not disposed above the stage 302 and the laser polishing system 300 includes one or more mirrors (not shown) used to direct the laser beam 308 from the laser source 306 to a desired spot on the surface of the workpiece 304.

In some embodiments, the laser polishing system 300 further includes an image sensor 310, such as a 3D scanner, which is used to map the surface of the workpiece 304 and to create a 3D image thereof. In some embodiments, the image sensor 310 is used to map the substrate contacting surfaces of a substrate support, the recessed surfaces of a substrate support, or the material surfaces of a showerhead disposed between holes formed through the plasma facing surface thereof. The image map is communicated to a system controller which controls the operation of the laser polishing system, including the movement of the stage 302 and the operation of the laser source 306. The image map is used by the system controller to selectively laser polish desired surfaces on the workpiece without exposing the in-between surfaces where laser polishing is not desired to the laser beam.

Herein, the laser source provides a pulsed laser beam having a spot size, i.e., the cross-sectional area of the beam, which is suitable for high resolution polishing of or between features of one or more of the processing components described herein. Here, the diameter of the spot is about 10 mm or less, such as about 5 mm or less, or for example 1 mm or less. In some embodiments, the spot size is about 500 mm² or less, such as about 150 mm² or less, or about 100 mm² or less. In some embodiments, the spot size is between about 0.001 mm² and about 10 mm², such as between about 0.001 mm² and about 5 mm², between about 0.001 mm² and about 1 mm², between about 0.001 mm² and about 0.5 mm², of for example between about 0.001 mm² and about 0.1 mm². In some embodiments, the spot size of the beam is about 10 mm² or less, such as 5 mm² or less, 2.5 mm² or less, 1 mm² or less, 0.5 mm² or less, 0.1 mm² or less, 0.5 mm² or less, or for example about 0.01 mm² or less.

Here, the pulse repetition rate, i.e., the pulse frequency of the laser beam is about 500 Hz or more, such as about 1 kHz or more, about 5 kHz or more, about 10 kHz or more, about 100 kHz or more, about 500 kHz or more, for example about 1 MHz or more. In some embodiments, the pulse frequency for a spot size between about 0.001 mm² and about 0.01 mm² is about 100 kHz or more, for example about 500 kHz or more. In some embodiments, the pulse frequency for a spot size between about 0.01 mm² and about 0.1 mm² is about 10 kHz or more, such as about 100 kHz or more. In some embodiments, the pulse frequency for a spot size between about 0.1 mm² and about 1 mm² is about 1 kHz or more. In some embodiments, the pulse frequency for a spot size more than about 1 mm² is about 1 kHz or more. In some embodiments, an average pulse duration is about 10 μs or less, such about 1 μs or less, about 0.5 μs or less, or for example about 0.1 μs or less. Typically, the on-time duty cycle of the pulsed beam is about 50% or less, such as about 40% or less, about 30% or less, about 20% or less, or for example about 10% or less. In some embodiments, the peak energy of each laser pulse is between about 4 μJ and about 500 μJ, or for example more than about 1 μJ, more than about 10 μJ, such as more than about 50 μJ, or more than about 100 μJ. In some embodiments, the pulse energy density of the laser beam is about 6000 mW/cm² or less, such as about 1000 mW/cm² or less, about 500 mW/cm² or less, about 250 mW/cm² or less, about 100 mW/cm² or less, about 50 mW/cm² or less, or for example about 10 mW/cm² or less. For example, in some embodiments the pulse frequency any one of the spot sizes or diameters or ranges of spot sizes or diameters described herein is between about 10 kHz and about 500 kHz, such as between about 50 kHz and about 250 kHz, the peak energy of each layer pulse is between about 50 μJ and 250 μJ, and the pulse energy density is about 100 mW/cm² or less, such as about 50 mW/cm² or less, for example about 25 mW/cm² or less.

Herein, one or both of the laser beam 308 and the stage 302 are moved in the x and y directions to provide scan the laser beam 308 across the surface of the workpiece 304 in order to facilitate the laser polishing thereof. The relative movement between the laser beam 308 and the workpiece 304 is controlled to provide each point on the surface to be polished exposure to 3 or more laser pulses (laser shots), or for example between about 3 and about 300 laser shots.

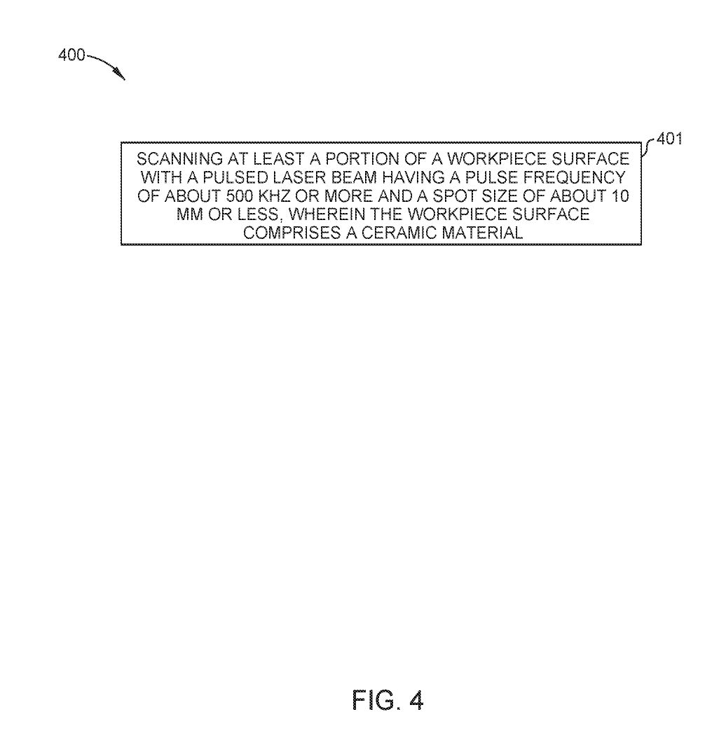

FIG. 4 sets forth a method of laser polishing a workpiece using the laser polishing system described in FIG. 3. At activity 401 the method 400 includes scanning, such as in a raster pattern, at least a portion of the workpiece surface with a pulsed laser beam having a pulse frequency of about 500 kHz or more and a spot size of about 10 mm² or less. Here, the workpiece surface comprises a ceramic material. Typically, scanning the pulsed laser beam across the surface of the workpiece heats the surface of the ceramic material against which the laser beam is directed to a temperature of more than the material's melting point but less than the material's evaporation point. Thus, scanning the laser beam across at least a portion of the workpiece surface desirably reflows the ceramic material to reduce the surface roughness and porosity thereof.

In some embodiments, the laser polishing methods describe herein reduce the surface roughness (Ra) of a ceramic coating by more than about 10%, such as more than about 20%. In some embodiments, the polishing methods reduce the porosity of a ceramic coating by more than about 30%, such as more than about 40%, for example more than about 50%. In some embodiments, the ceramic coating comprises yttrium and the laser polishing methods described herein reduce the surface roughness (Ra) of the yttrium based coating by about 20% or more the porosity of about 50% or more.

In some embodiments, the workpiece is a processing component to be used with or in a plasma processing chamber, such as the processing chamber described in FIG. 1. In some embodiments, the workpiece comprises one of a gas injector, a showerhead, a substrate support, a support shaft, a door, a liner, a shield, or a robot end effector. In some embodiments, the ceramic material comprises one or a combination of silicon carbide (SiC) or a fluoride, oxide, oxyfluoride, nitride, or oxynitrides of Group III, Group IV, or Lanthanide series elements. In some embodiments, the processing component has been previously used is a plasma processing chamber and the laser polishing methods set forth herein are used to resurface the processing component to repair chemical corrosion or plasma induced erosion damage thereto.

In some embodiments, the processing component comprises a showerhead formed of a quartz substrate further including an yttrium based protective coating disposed on a plasma facing surface thereof. The yttrium based protective coating is deposited onto the surface of the quartz substrate before a plurality of holes are formed therethrough. Thus, the interior surfaces of the holes comprise exposed quartz. Here, laser polishing the showerhead includes scanning the pulsed laser beam across the yttrium based protective coating disposed between individual ones of a plurality of holes. In other embodiments, the surface to be laser polished comprises a plasma facing surface of a quartz showerhead with or without a protective coating where the laser polishing is used to repair plasma induced erosion damage to the surface thereof. Beneficially, the laser spot sizes used with the methods described herein provide sufficient resolution to laser polish up to the edges of the plurality of holes without the laser beam traveling into the holes. This relatively high resolution allows for substantially complete laser polishing of the plasma facing surface of the showerhead without causing undesirable damage or undesirable reflow to the exposed quartz surface inside of the holes or the reflow of the yttrium based coating or quartz surface into the holes.

In some embodiments, the to be laser polished surface of the processing component comprises the patterned surface of a substrate support, such as the substrate support described in FIGS. 2A-2B. In some embodiments, polishing the patterned surface of the substrate support comprises laser polishing one but not both of the substrate contacting surfaces of the elevated regions or the recessed regions disposed there between.

Exemplary laser polishing parameters which may be used with the embodiments described herein are set forth in Columns A, B, and C of Table 1. In the example of Column A, the method provides a laser beam pulse energy density from 5 mW/cm² to 25 mW/cm². In the example of Column B, the method provides a laser beam pulse energy density from 50 mW/cm² to 250 mW/cm². In the example of Column C, the method provides a laser beam pulse energy density from 1500 mW/cm² to 6000 mW/cm².

| EXAMPLE LASER | | | | | | |
|---|---|---|---|---|---|---|
| BEAM PARAMETERS | A | | B | | C | |
| Spot Size (mm²) | 0.001257 | | 3.1 | | 314 | |
| Spot Diameter (mm) | 0.10 | | 1.0 | | 10.0 | |
| Pulse Frequency | 1 | MHz | 10 | kHz | 1 | kHz |
| Average Pulse Energy | 3,185 | | 127 | | 12.7 | |
| Density (mW/cm²) | | | | | | |
| Shots per laser spot | 3 | | 25 | | 250 | |
| Pulse Duration (s) | 9 × 10⁻⁸ | | 9 × 10⁻⁸ | | 9 × 10⁻⁸ | |
| # spots for 100% | 76562500 | | 30,625 | | 306 | |
| coverage | | | | | | |
| Theoretical process | 0.34 | | 0.0011 | | 0.00011 | |
| time (min) | | | | | | |
| Peak Energy (μJ) | 40 | μJ | 100 | μJ | 400 | μJ |

While the foregoing is directed to embodiments of the present disclosure, other and further embodiments of the disclosure may be devised without departing from the basic scope thereof, and the scope thereof is determined by the claims that follow.

What is claimed is:

1. A method of laser polishing a workpiece surface, comprising:
scanning at least a portion of the workpiece surface with a pulsed laser beam having a pulse frequency of about 50 kHz or more and a spot size of about 10 mm² or less, wherein the workpiece surface comprises a ceramic material.

2. The method of claim 1, wherein the workpiece is a processing component for use with a plasma processing chamber.

3. The method of claim 2, wherein the workpiece comprises one of a gas injector, a showerhead, a substrate support, a support shaft, a door, a liner, a shield, or a robot end effector.

4. The method of claim 3, wherein the ceramic material comprises silicon carbide (SiC), quartz, aluminum oxide (Al₂O₃), aluminum nitride (AlN), titanium oxide (TiO), titanium nitride (TiN), yttrium oxide (Y₂O₃), yttrium fluoride (YF₃), yttrium oxyfluoride (YOF), or yttrium-stabilized zirconia.

5. The method of claim 2, wherein the workpiece surface is a patterned surface of a substrate support, the patterned surface comprising a plurality of elevated features extending from one or more recessed regions.

6. The method of claim 5, wherein a substrate contacting surface area of the patterned surface is less than about 30% of a non-device side surface area of a substrate to be disposed on the substrate support.

7. The method of claim 2, wherein
wherein the processing component comprises a quartz showerhead having plasma facing surface comprising quartz or an yttrium based protective coating, and
laser polishing the workpiece surface comprises scanning the pulsed laser beam across the quartz or yttrium based coating disposed between holes formed in the plasma facing surface.

8. The method of claim 7, wherein laser polishing the workpiece surface does not comprise scanning the pulsed laser beam across the holes formed in the plasma facing surface.

9. The method of claim 8, wherein the spot size of the laser is about 1 mm² or less.

10. The method of claim 1, wherein the ceramic material comprises one or a combination of silicon carbide (SiC), quartz, or a fluoride, oxide, oxyfluoride, nitride, or oxynitrides of Group III, Group IV, or Lanthanide series elements.

11. The method of claim 10, wherein the ceramic material comprises silicon carbide (SiC), quartz, aluminum oxide (Al₂O₃), aluminum nitride (AlN), titanium oxide (TiO), titanium nitride (TiN), yttrium oxide (Y₂O₃), yttrium fluoride (YF₃), yttrium oxyfluoride (YOF), or yttrium-stabilized zirconia.

12. A method of laser polishing a workpiece surface, comprising:
scanning at least a portion of the workpiece surface with a pulsed laser beam having a pulse frequency of about 50 kHz or more and a spot size of about 10 mm² or less, wherein
the workpiece surface comprises a ceramic material, and
the workpiece is a processing component for use with a plasma processing chamber, comprising one of a gas injector, a showerhead, a substrate support, a support shaft, a door, a liner, a shield, or a robot end effector.

13. The method of claim 12, wherein the ceramic material comprises silicon carbide (SiC), quartz, aluminum oxide (Al₂O₃), aluminum nitride (AlN), titanium oxide (TiO), titanium nitride (TiN), yttrium oxide (Y₂O₃), yttrium fluoride (YF₃), yttrium oxyfluoride (YOF), or yttrium-stabilized zirconia.

14. The method of claim 12, wherein the processing component comprises a quartz showerhead having plasma facing surface comprising quartz or an yttrium based protective coating, and
laser polishing the workpiece surface comprises scanning the pulsed laser beam across the quartz or yttrium based coating disposed between holes formed in the plasma facing surface.

15. The method of claim 14, wherein the workpiece surface is a patterned surface of a substrate support, the patterned surface comprising a plurality of elevated features extending from one or more recessed regions.

16. The method of claim 15, wherein a substrate contacting surface area of the patterned surface is less than about 30% of a non-device side surface area of a substrate to be disposed on the substrate support.

17. A method of laser polishing a workpiece surface, comprising:
scanning at least a portion of the workpiece surface with a pulsed laser beam having a pulse frequency of about 50 kHz or more and a spot size of about 10 mm² or less, wherein
the workpiece surface comprises a nitride, fluoride, oxide, oxynitride, or an oxyfluoride of aluminum, titanium, or yttrium, and
the workpiece is a processing component for use with a plasma processing chamber, comprising one of a gas injector, a showerhead, a substrate support, a support shaft, a door, a liner, a shield, or a robot end effector.

18. The method of claim 17, wherein
wherein the processing component comprises a quartz showerhead having plasma facing surface comprising quartz or an yttrium based protective coating, and
laser polishing the workpiece surface comprises scanning the pulsed laser beam across the quartz or yttrium based coating disposed between holes formed in the plasma facing surface.

19. The method of claim 17, wherein the workpiece surface is a patterned surface of a substrate support, the patterned surface comprising a plurality of elevated features extending from one or more recessed regions.

20. The method of claim 19, wherein a substrate contacting surface area of the patterned surface is less than about 30% of a non-device side surface area of a substrate to be disposed on the substrate support.
